(19) United States
(12) Patent Application Publication
(10) Pub. No.: US 2025/0143193 A1
(43) Pub. Date: May 1, 2025

(54) MANUFACTURING METHOD

(71) Applicants: STMicroelectronics International N.V., Geneva (CH); COMMISSARIAT A L'ENERGIE ATOMIQUE ET AUX ENERGIES ALTERNATIVES, Paris (FR)

(72) Inventors: Latifa DESVOIVRES, Grenoble (FR); Jerome DUBOIS, Grenoble (FR); Daniel BENOIT, Grenoble (FR); Pascal GOURAUD, Montbonnot St Martin (FR)

(73) Assignees: STMicroelectronics International N.V., Geneva (CH); COMMISSARIAT A L'ENERGIE ATOMIQUE ET AUX ENERGIES ALTERNATIVES, Paris (FR)

(21) Appl. No.: 18/923,201

(22) Filed: Oct. 22, 2024

(30) Foreign Application Priority Data
Oct. 31, 2023 (FR) 2311846

(51) Int. Cl. H10N 70/00; H10B 63/10; H10N 70/20

(52) U.S. Cl. CPC H10N 70/063; H10B 63/10; H10N 70/231; H10N 70/8265; H10N 70/8413

(57) ABSTRACT

The present description relates to a method of manufacturing an electronic device comprising a phase-change memory cell, the method comprising: the forming of a first layer made of a resistive material; the forming of a stack of layers on the first layer, the stack comprising at least one second layer made of a phase-change material; the etching of the stack, said etching stopping when the first layer is reached around the location of the memory cell; the forming of a spacer on the side walls of the stack; then an etching of the first layer, so that the stack rests on a central portion of the first layer and that the spacer rests on a peripheral portion of the first layer.

### CROSS-REFERENCE TO RELATED APPLICATION(S)

The present disclosure is based on, and claims the priority of, French patent application FR2311846, filed on Oct. 31, 2023, and having for title “Procédé de fabrication,” the content of which is incorporated by reference, within the limits authorized by Law.

### BACKGROUND

### Technical Field

The present description generally concerns electronic devices and their manufacturing methods, and more particularly phase-change memory devices.

### Description of the Related Art

In a conventional phase-change memory, each memory cell comprises, for example, a layer of phase-change material which is in contact with a resistive element. Phase-change materials are materials which can switch between a crystalline phase and an amorphous phase. This switching is triggered by an increase in the temperature of the resistive element through which an electric current is circulated. The difference in electrical resistance between the amorphous phase of the material and its crystalline phases is used to define at least two memory states, arbitrarily 0 and 1.

Memories are generally arranged in the form of arrays, comprising word lines and bit lines, that is, rows and columns. A memory cell, containing binary information, is located at each intersection of a row and a column.

The information contained in a cell of a phase-change memory is for example accessed to, or read, by measuring the resistance between the bit line and word line of the memory cell.

Phase-change memory cells are for example located in an interconnection network. By interconnection network, there is meant a stack of insulating layers, formed during the manufacturing steps called “back end of line,” having metal tracks coupled together by conductive vias located therein. Preferably, the levels of the interconnection network, each comprising conductive tracks in an insulating layer and conductive vias in an insulating layer, have a constant height.

Certain phase-change memory cell manufacturing methods comprise a step of etching of a metal layer. The metal layer is for example made of a material etchable by the same etching methods as the phase-change material of the memory cell. Thus, such methods risk causing an unintentional etching of the phase-change material, which may result in performance decreases.

### BRIEF SUMMARY

An embodiment provides a method of manufacturing an electronic device comprising a phase-change memory cell, the method comprising: the forming of a first layer made of a resistive material; the forming of a stack of layers on the first layer, the stack comprising at least one second layer made of a phase-change material; the etching of the stack, said etching stopping when the first layer is reached around the location of the memory cell; the forming of a spacer on the side walls of the stack; then, an etching of the first layer, so that the stack rests on a central portion of the first layer and that the spacer rests on a peripheral portion of the first layer.

Another embodiment provides an electronic device comprising a memory cell, the phase-change memory cell comprising: a first layer made of a resistive material; a stack of layers resting on a central portion of the first layer, the stack comprising at least one second layer made of a phase-change material; and a spacer resting on the side walls of the stack and on a peripheral portion of the first layer.

According to an embodiment, the second layer is in contact with the first layer.

According to an embodiment, the first layer is entirely covered by the stack and spacer.

According to an embodiment, the first layer is made of a material having a resistivity greater than 10 mΩ/cm.

According to an embodiment, the maximum distance between an inner wall of the spacer and the nearest outer wall of the spacer is shorter than 5 nm.

According to an embodiment, the thickness of the first layer is in the range from 2 nm to 3 nm.

According to an embodiment, the stack comprises at least one third layer made of a conductive material covering the second layer.

According to an embodiment, the stack comprises at least one fourth layer made of an insulating material covering the third layer.

According to an embodiment, the second layer is made of an alloy comprising at least one chalcogen element.

According to an embodiment, the first layer is in contact with an L-shaped resistive element.

According to an embodiment, the first layer is made of a refractory metal and/or a refractory metal nitride, for example of tantalum, of tungsten, of TiSiN, of TiN, or of TaN.

According to an embodiment, the spacer is made of SiCl4, of SiN, or of SiC.

According to an embodiment, the forming of the spacer is performed in the same enclosure as the step of etching of the stack, the device not having been removed from the enclosure between the steps.

According to an embodiment, the etching of the stack forms a pattern of the stack on the first layer.

According to an embodiment, the step of etching of the stack is preceded by the forming of an etch mask covering the location of the memory cell.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of a device comprising a memory cell;

FIG. 2 illustrates a step of a method of manufacturing an electronic device;

FIG. 3 illustrates another step of a method of manufacturing an electronic device;

FIG. 4 illustrates another step of a method of manufacturing an electronic device;

FIG. 5 illustrates another step of a method of manufacturing an electronic device; and

FIG. 6 illustrates another step of a method of manufacturing an electronic device.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%.

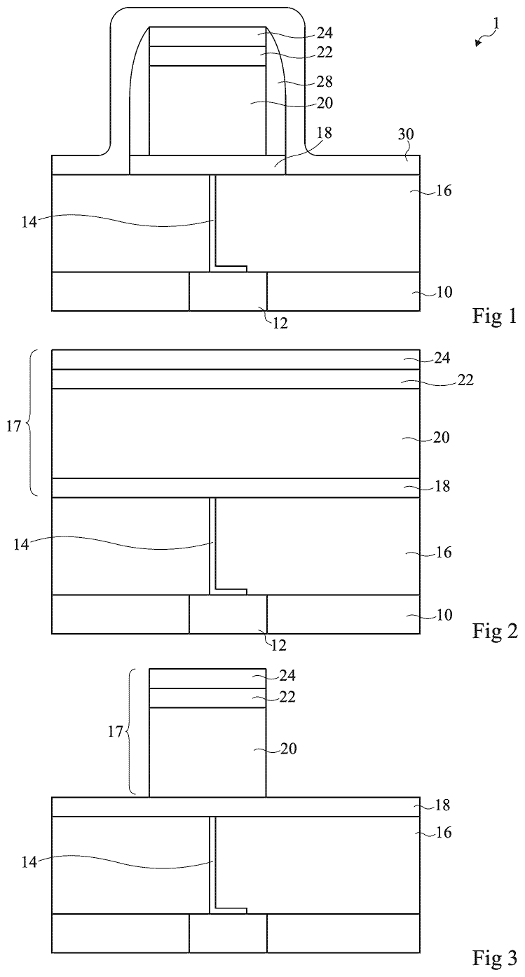

FIG. 1 shows an embodiment of a device comprising a memory cell 1.

The device comprises an insulating layer 10 located, for example, on a substrate, not shown. A conductive element 12, for example a via or a wall, is located in layer 10. Element 12 crosses layer 10 from an upper surface to a lower surface, for example so as to reach the substrate in contact with the lower surface.

The device further comprises a resistive element 14, for example having an L shape. More specifically, the device comprises an insulating layer 16 crossed by resistive element 14 so as to reach conductive element 12. Element 14 for example comprises a horizontal portion resting on element 12 and a vertical portion extending between the lower and upper surfaces of layer 16, so as to be in contact with element 12 and to have one end flush with the upper surface of layer 16.

The device further comprises a layer 18. Layer 18 partially covers layer 16. More specifically, layer 18 covers, and is in contact with, the upper end of element 14 flush with the upper surface of layer 16, and the upper surface of layer 16 surrounding the upper end of element 14. Layer 18 is preferably a planar layer.

Layer 18 preferably has a constant thickness. Layer 18 for example has a thickness in the range from 2 nm to 3 nm.

Layer 18 is made of a material, preferably a metal, having a high resistivity. In other words, layer 18 has a resistivity at least equal to 10 mΩ/cm. Layer 18 is preferably made of the same material as the material of resistive element 14. Layer 18 is for example made of a refractory metal and/or a refractory metal nitride. Layer 18 is for example made of tantalum, of tungsten, of TiSiN, of TiN, or of TaN.

The device further comprises a stack of layers comprising at least one layer 20 made of a phase-change material. In the example of FIG. 1, said stack further comprises a layer 22 and a layer 24.

Layers 20, 22, 24 preferably have substantially identical lateral dimensions. The side walls of layers 20, 22, 24 are preferably coplanar.

Layer 18 covers a central portion of layer 14. Thus, a central portion of the upper surface of layer 18 is covered by, and in contact with, layer 20. A peripheral portion of the upper surface of layer 18 is not covered by layer 20. The peripheral portion is not covered by layers 22 or 24. The peripheral portion entirely surrounds the central portion.

Layer 20 is made of a phase-change material, that is, a material changing phase when layer 20 is submitted to a programming current having a value higher than a threshold. Layer 20 is for example made of a homogeneous material, that is, each portion of layer 20 is made of the same material, preferably by the same proportions. Layer 20 preferably comprises a chemical element from the chalcogen family. The chalcogen family more specifically comprises oxygen, sulfur, selenium, tellurium, and polonium. Layer 20 is for example a chalcogen element alone or, preferably, an alloy comprising a chalcogen element. Layer 20 is, for example, made of an alloy of germanium, of antimony, and of tellurium. Layer 20 is for example made of an alloy of germanium and of tellurium. More generally, layer 20 is for example made of an alloy of germanium and of at least another chemical element from at least one of columns 13, 14, 15, and 16 of the periodic table of elements. It is considered that the elements of column 13 are boron, aluminum, gallium, indium, thallium, and nihonium. It is considered that the elements of column 14 are carbon, silicon, germanium, tin, lead, and flerovium. It is considered that the elements of column 15 are nitrogen, phosphorus, arsenic, antimony, bismuth, and moscovium. It is considered that the elements of column 16 are oxygen, sulfur, selenium, tellurium, polonium, and livermorium.

Preferably, layer 20 has a constant thickness. Layer 20 for example has a thickness in the range from 40 nm to 60 nm.

Layer 22 preferably entirely covers layer 20. Layer 22 is preferably entirely in contact with layer 20. Layer 22 is a conductive layer, for example made of metal, for example of titanium nitride.

Layer 24 preferably entirely covers layer 22. Layer 24 is preferably entirely in contact with layer 22. Layer 24 is an insulating layer, for example made of silicon nitride.

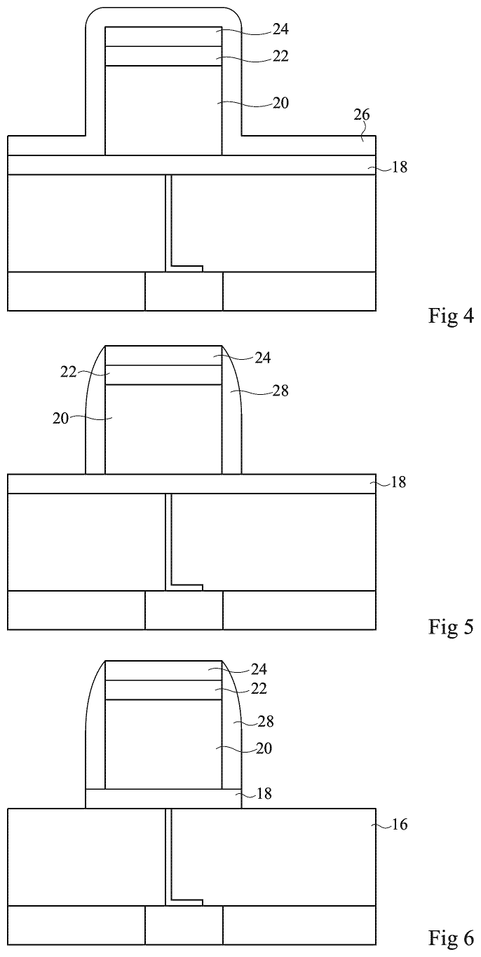

The device comprises spacers 28 extending over the side walls of layers 20, 22, 24. Spacers 28 are made of an insulating material, for example SiCl4, SiN, or SiC. Spacers 28 extend at least over the side walls of layer 20. Spacers 28 extend from the upper surface of layer 18. Spacers 28 extend at least up to the upper surface of layer 20. In the example of FIG. 4, spacers 28 extend up to the upper surface of layer 24.

The maximum thickness of spacers 28, that is, the maximum distance between an inner wall of a spacer and the nearest outer wall, is preferably smaller than 5 nm, preferably in the range from 2 nm to 3 nm. By inner wall, there is meant the wall in contact with layers 20, 22, 24. By outer wall, there is meant the wall opposite to the inner wall, that is, the wall in contact neither with layer 18 nor with layers 20, 22, 24.

Spacers 28 entirely cover the peripheral portion of the upper surface of layer 18. The upper surface of layer 18 is thus entirely covered by layer 20 and spacers 28.

The device further comprises a passivation layer 30 on the memory cell. Layer 30 is made of an insulating material, for example, silicon nitride or silicon carbide. Layer 30 covers, preferably conformally, the upper surface of layer 16, the side walls of layer 18, spacers 28, and the upper surface of layer 24.

FIGS. 2 to 6 illustrate steps, preferably successive, of a method of manufacturing an electronic device comprising a memory. More specifically, FIGS. 1 to 6 illustrate a method of manufacturing a memory cell of the device. The described method may of course be used to manufacture a plurality of memory cells.

FIG. 2 illustrates a step of an electronic device manufacturing method.

During this step, an insulating layer 10 is formed, for example on a substrate, not shown. A conductive element 12, for example a via or wall, is formed in layer 10. Element 12 crosses layer 10 from an upper surface to a lower surface, for example to reach the substrate in contact with the lower surface.

The step of FIG. 2 further comprises the forming of a resistive element 14, for example having an L shape. More specifically, the step of FIG. 2 comprises the forming of an insulating layer 16 and the forming of the resistive element 14 crossing layer 16 and reaching conductive element 12. Element 14 for example comprises a horizontal portion resting on element 12 and a vertical portion extending between the lower and upper surfaces of layer 16, so as to be in contact with element 12 and to have one end flush with the upper surface of layer 16.

The step of FIG. 2 further comprises the forming of a stack 17 of layers on layer 16 and on the upper end of element 14. Stack 17 is for example formed over the entire structure resulting from the forming of layer 16 and of element 14. Stack 17 covers at least the locations of the memory cells.

Stack 17 comprises a lower layer 18. Layer 18 is thus the layer of stack 17 closest to layer 16. More specifically, layer 18 covers layer 16 and the upper end of element 14. Preferably, layer 18 entirely covers the upper surface of layer 16, that is, the surface of layer 16 most distant from layer 10. Layer 18 covers, and is in contact with, the end of the vertical portion of element 14 flush with the upper surface of layer 16. Layer 18 is preferably a planar layer.

Layer 18 preferably has a constant thickness. For example, layer 18 has a thickness in the range from 2 nm to 3 nm.

Layer 18 is made of a material, preferably a metal, having a high resistivity. In other words, layer 18 has a resistivity of at least 10 mΩ/cm. Layer 18 is preferably made of the same material as the material of resistive element 14. Layer 18 is for example made of a refractory metal and/or a refractory metal nitride. For example, layer 18 is made of tantalum, of tungsten, of TiSiN, of TiN, or of TaN.

Stack 17 comprises a layer 20. Layer 20 is made of a phase-change material, that is, a material changing phase when layer 20 is submitted to a programming current having a value higher than a threshold. Layer 20 covers, preferably entirely, layer 18. Layer 20 is preferably entirely in contact with layer 18.

Layer 20 is for example made of a homogeneous material, that is, each portion of layer 20 is made of the same material, preferably by the same proportions. Layer 20 preferably comprises a chemical element from the chalcogen family. The chalcogen family more specifically comprises oxygen, sulfur, selenium, tellurium, and polonium. Layer 20 is for example a chalcogen element alone or, preferably, an alloy comprising a chalcogen element. Layer 20 is for example an alloy of germanium, of antimony, and of tellurium. Layer 20 is for example made of an alloy of germanium and of tellurium. More generally, layer 20 is for example made of an alloy comprising at least germanium and a chalcogen element. Layer 20 is for example made of an alloy comprising germanium, a chalcogen element, and at least one element from columns 13, 14, 15, 16 of the periodic table of elements.

Layer 20 preferably has a constant thickness. Layer 20 for example has a thickness in the range from 40 nm to 60 nm.

Stack 17 may comprise a layer 22. Layer 22 covers, preferably entirely, layer 20. Layer 22 is preferably entirely in contact with layer 20. Layer 20 is a conductive layer, for example made of metal, for example of titanium nitride.

Stack 17 may comprise a layer 24. Layer 24 covers, preferably entirely, layer 22. Layer 24 is preferably entirely in contact with layer 22. Layer 24 is an insulating layer, for example made of silicon nitride.

FIG. 3 illustrates another step of a method of manufacturing an electronic device.

During this step, stack 17, except for layer 18, is etched outside of the locations of the memory cells. In other words, in the example of FIG. 3, layers 20, 22, 24 are etched around the location of the memory cell. Thus, the step of FIG. 3 for example comprises a step of etching, down to the upper surface of layer 18, of the stack 17 in which the portions of stack 17 located between the memory cell columns are etched, and a step of etching, down to the upper surface of layer 18, of the stack 17 in which the portions of stack 17 located between the memory cell rows are etched.

The etching performed at the step of FIG. 3 is configured to reach the upper surface of layer 18. Layer 18 is not etched during the step of FIG. 3.

FIG. 4 illustrates another step of an electronic device manufacturing method.

During this step, a layer 26 is conformally formed on the structure resulting from the step of FIG. 3. Preferably, layer 26 covers the entire structure resulting from the step of FIG. 3. Layer 26 covers, in particular, the upper surface of layer 18, the side walls of the layers of stack 17 having been etched during the step of FIG. 3, and the upper surface of the upper layer of stack 17, that is, layer 24 in the example of FIG. 4.

Layer 26 is made of an insulating material. Layer 26 is for example made of silicon nitride. Layer 26 corresponds, for example, to a stack of one or a plurality of silicon nitride layers and of one or a plurality of silicon carbide layers. Layer 26 preferably has a thickness smaller than 5 nm, for example in the range from 2 nm to 3 nm.

According to a first embodiment, layer 26 is formed ex situ, that is, outside of the enclosure where the etching step of FIG. 3 is carried out. The layer is then formed by depositing a layer of silicon nitride or layers made of silicon nitride and of silicon carbide.

According to a second embodiment, layer 26 is formed in situ, that is, in the enclosure where the etching step of FIG. 3 is carried out. Preferably, the structure resulting from the step of FIG. 3 is not taken out of said enclosure between the step of FIG. 3 and the forming of layer 26. The forming of layer 26, for example comprising silicon, nitrogen, and chlorine, for example comprises the forming of a plasma and the application of SiCl4 and N2 gases.

FIG. 5 illustrates another step of an electronic device manufacturing method.

The step of FIG. 5 comprises a step of anisotropic etching of layer 26. More specifically, the step of FIG. 5 comprises the forming of spacers 28 extending, for example, over the side walls of layers 20, 22, 24. Spacers 28 extend at least over the side walls of layer 20. Spacers 28 extend from the upper surface of layer 18. Spacers 28 extend at least up to the upper surface of layer 20. In the example of FIG. 5, spacers 28 extend up to upper surface of layer 24.

The maximum thickness of spacers 28, that is, the maximum distance between an inner wall of a spacer and the nearest outer wall, is preferably smaller than 5 nm, preferably in the range from 2 nm to 3 nm. By inner wall, there is meant the wall in contact with layers 20, 22, 24. By outer wall, there is meant the wall opposite to the inner wall, that is, the wall which is in contact neither with layer 18 nor with layers 20, 22, 24.

FIG. 6 illustrates another step of an electronic device manufacturing method.

The step of FIG. 6 comprises a partial etching of layer 18. More specifically, the portions of layer 18 surrounding the cells are etched. In other words, the portions of layer 18 which are not protected by spacers 28 and layers 20, 22, 24 are etched.

The method of etching layer 18 is, for example, a chemical etching, for example based on chlorine. The etching of layer 18 is preferably carried out by the same etching method as that used to etch layers 20, 22, 24. The etching is preferably an etching of the material of layer 18 selective over the material of layer 24 and the material of spacer 28. By selective, there is meant that the etching etches the material of layer 18 at least twice as fast as the materials of layer 24 and of spacers 28.

Layer 18 comprises side walls coplanar with the outer walls of the lower portions of the spacers. Layer 18 is thus entirely covered by the spacers and layer 20.

The method also comprises a step subsequent to the step of FIG. 6. During this step, a passivation layer, not shown, is formed on the memory cell. More specifically, a layer made of an insulating material, for example silicon nitride or silicon carbide, is formed, preferably conformally, on the structure resulting from the step of FIG. 5. The layer thus covers the upper surface of layer 16, the side walls of layer 18, spacers 28, and the upper surface of layer 24.

It could have been chosen not to form spacers 28 and to etch layer 18 at the same time as the rest of stack 17. However, the material of layers 20, 22, 24 is etched faster than the material of layer 18. Thus, during the etching of layer 18, layer 20, located at the location of the memory cell, would be etched from the side walls. The profile of the cell and its critical dimensions would then not correspond to the targeted values. Further, there could be a critical dimension and profile variation between cells of the same device.

An advantage of the described embodiments is that it is possible to etch the stack comprising the highly resistive layer and the phase-change material without causing damage to the layer of phase-change material.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

A method of manufacturing an electronic device (1) including a phase-change memory cell, is summarized as including: the forming of a first layer (18) made of a resistive material; the forming of a stack of layers (20, 22, 24) on the first layer (18), the stack including at least one second layer (20) made of a phase-change material; the etching of the stack (20, 22, 24), said etching stopping when the first layer (18) is reached around the location of the memory cell; the forming of a spacer (28) on the side walls of the stack (20, 22, 24); then an etching of the first layer (18), so that the stack (20, 22, 24) rests on a central portion of the first layer (18) and that the spacer (28) rests on a peripheral portion of the first layer (18).

An electronic device (1) is summarized as including a memory cell, the phase-change memory cell including: a first layer (18) made of a resistive material; a stack of layers (20, 22, 24) resting on a central portion of the first layer (18), the stack including at least one second layer (20) made of a phase-change material; and a spacer (28) resting on the side walls of the stack and on a peripheral portion of the first layer (18).

The second layer (20) is in contact with the first layer (18).

The first layer (18) is entirely covered by the stack (20, 22, 24) and the spacer (28).

The first layer (18) is made of a material having a resistivity greater than 10 mΩ/cm.

The maximum distance between an inner wall of the spacer (28) and the nearest outer wall of the spacer (28) is shorter than 5 nm.

The thickness of the first layer (18) is in the range from 2 nm to 3 nm.

The stack (20, 22, 24) includes at least one third layer (22) made of a conductive material covering the second layer (20).

The stack (20, 22, 24) includes at least one fourth layer (24) made of an insulating material covering the third layer (22).

The second layer (20) is made of an alloy including at least one chalcogen element.

The first layer (18) is in contact with an L-shaped resistive element (14).

The first layer (18) is made of a refractory metal and/or a refractory metal nitride, for example of tantalum, of tungsten, of TiSiN, of TiN, or of TaN.

The spacer (28) is made of SiCl4, of SiN, or of SiC.

The forming of the spacer (28) is carried out in the same enclosure as the step of etching of the stack (20, 22, 24), the device not having been removed from the enclosure between the steps.

The etching of the stack (20, 22, 24) forms a pattern of the stack on the first layer (18).

The step of etching of the stack is preceded by the forming of an etch mask covering the location of the memory cell.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic device, comprising:
forming a first layer of a resistive material on a first insulating layer, the first insulating layer including a resistive element extending along a first direction from a first side of the first insulating layer to a second side opposite the first side, the resistive element being coupled to the first layer and to a conductive element on the second side;
forming a stack of layers on the first layer, the stack including at least one second layer of a phase-change material;
etching the stack along the first direction, the etching stopping when the first layer is reached;
forming a spacer on each of a plurality of side walls of the stack, the side walls extending along the first direction; and
etching the first layer along the first direction to the first insulating layer, so that the stack is on a central portion of the first layer and the spacer is on a peripheral portion of the first layer.

2. The method according to claim 1, wherein the conductive element is in a second insulating layer, the second insulating layer covering the second side of the first insulating layer.

3. The method according to claim 1, wherein the second layer is in contact with the first layer.

4. The method according to claim 1, wherein, during the forming the spacer, the first layer is entirely covered by the stack and the spacer.

5. The method according to claim 1, wherein the first layer includes a material having a resistivity greater than 10 mΩ/cm.

6. The method according to claim 1, wherein a maximum distance, along a second direction transverse to the first direction, between an inner wall of the spacer on one of the plurality of sidewalls and an outer wall of the spacer is smaller than 5 nm.

7. The method according to claim 1, wherein a thickness of the first layer along the first direction is in the range of 2 nm and 3 nm.

8. The method according to claim 1, wherein the stack includes at least one third layer made of a conductive material covering the second layer.

9. The method according to claim 8, wherein the stack includes at least one fourth layer made of an insulating material covering the third layer.

10. The method according to claim 1, wherein the second layer is made of an alloy comprising at least one chalcogen element.

11. The method according to claim 1, wherein the resistive element is L-shaped.

12. The method according to claim 1, wherein the first layer is made of a refractory metal.

13. The method according to claim 1, wherein the forming the spacer is carried out in the same enclosure as the etching the stack, the device not having been removed from the enclosure between the steps.

14. The method according to claim 1, wherein the etching the stack forms a pattern of the stack on the first layer.

15. The method according to claim 1, wherein the etching the stack is preceded by a forming of an etch mask covering a location of the memory cell.

16. An electronic device, comprising:
a first insulating layer having a first side opposite a second side along a first direction;
a second insulating layer on the first side;
a conductive element in the second insulating layer;
a first resistive layer on the second side of the first insulating layer;
an L-shaped resistive element extending entirely through the first insulating layer from the first resistive layer to the conductive element;
a stack of layers resting on a central portion of the first layer, the stack comprising at least one phase-change layer; and
a spacer covering a plurality of side walls of the stack and on a peripheral portion of the first layer.

17. The device according to claim 16, wherein the spacer includes one of silicon tetrachloride (SiCl4), silicon nitride (SiN), or silicon carbide (SIC).

18. The device according to claim 16, wherein the L-shaped resistive element includes a first portion extending along the first direction coupled between the first resistive layer and the conductive element and a second portion extending along a second direction transverse to the first direction, the second portion being coplanar with the first side of the first insulating layer.

19. A method of manufacturing an electronic device, comprising:
forming a first, resistive layer on a first side of a first insulating layer, the first insulating layer including an L-shaped resistive element extending entirely from the first side to a second side opposite the first side;
forming a stack of layers on the first layer, the stack including at least one second, phase-change layer;
etching the stack from a first surface of the stack entirely through the second, phase-change layer to the first layer;
forming a second insulating layer on the first surface of the stack, each of a plurality of side walls of the stack transverse to the first surface of the stack, and the first, resistive layer;
forming a spacer on each of the plurality of side walls by etching the second insulating layer to the first, resistive layer; and
etching the first layer to the first insulating layer.

20. The method according to claim 19, further comprising a second insulating layer on the second side of the first insulating layer and a conductive element in the second insulating layer, the L-shaped resistive element being directly coupled to the first, resistive layer and to the conductive element.
